(19) United States
(12) Patent Application Publication
(10) Pub. No.: US 2026/0215276 A1
(43) Pub. Date: Jul. 23, 2026

(54) SEMICONDUCTOR PACKAGE AND METHOD OF FORMING THE SAME

(71) Applicant: Taiwan Semiconductor Manufacturing Company, Ltd., Hsinchu (TW)

(72) Inventors: Shu-Huai Hsu, Keelung City (TW); Shih-Hui Wang, New Taipei City (TW); Yung-Ping Chiang, Hsinchu County (TW)

(73) Assignee: Taiwan Semiconductor Manufacturing Company, Ltd., Hsinchu (TW)

(21) Appl. No.: 19/034,522

(22) Filed: Jan. 22, 2025

(51) Int. Cl. H01L 23/00; H01L 21/56; H01L 21/762; H01L 23/31; H01L 23/367; H01L 23/538; H01L 25/16; H10B 80/00; H10D 80/30

(52) U.S. Cl. CPC H10W 42/121; H10P 90/1906; H10W 10/021; H10W 10/061; H10W 10/181; H10W 10/20; H10W 70/611; H10W 90/401; H10B 80/00; H10D 80/30; H10W 40/22; H10W 72/952; H10W 74/01; H10W 74/10; H10W 74/141; H10W 80/312; H10W 80/327; H10W 90/00; H10W 90/794

(57) ABSTRACT

A method of forming a semiconductor package includes the following operations. Semiconductor dies are bonded to an interposer structure. An encapsulation layer is formed around the semiconductor dies. A trench is formed along a periphery of the semiconductor dies, and the trench penetrates through the interposer structure and extends into portions of the semiconductor dies.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor packages have been generally adequate for their intended purposes, they have not been entirely satisfactory in all respects.

### BRIEF DESCRIPTION OF THE DRAWINGS

FIG. 1 to FIG. 8 are schematic cross-sectional views of a method of forming a semiconductor package in accordance with some embodiments.

FIG. 9A and FIG. 9B are simplified local top views of semiconductor packages in accordance with some embodiments.

FIG. 10 is a schematic cross-sectional view of a semiconductor package in accordance with some embodiments.

FIG. 11A and FIG. 11B are simplified local top views of semiconductor packages in accordance with some embodiments.

FIG. 12 is a schematic cross-sectional view of a semiconductor package in accordance with some embodiments.

FIG. 13A and FIG. 13B are simplified local top views of semiconductor packages in accordance with some embodiments.

FIG. 14 illustrates a method of forming a semiconductor package in accordance with some embodiments.

FIG. 15 illustrates a method of forming a semiconductor package in accordance with some embodiments.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose semiconductor packages and forming methods thereof. In a semiconductor package containing various dies, bonding defects are more likely to occur near the edges of the semiconductor package, especially at the corners, due to warpage or mismatches in the coefficient of thermal expansion (CTE) between the dies and the encapsulation layer. The bonding defects, including cracks at the bonding interface, may propagate along the bonding interface and accordingly lead to the delamination issue. However, such bonding defects are not observed in the disclosure. Specifically, in the disclosure, a trench is formed to remove the delaminated edge region of the bonding area between the die and the underlying interposer, and the trench is then filled with insulating materials. By such manner, the delaminated edge region is eliminated, the bonding performance is improved, the bonding stress is mitigated, and the package reliability is accordingly enhanced.

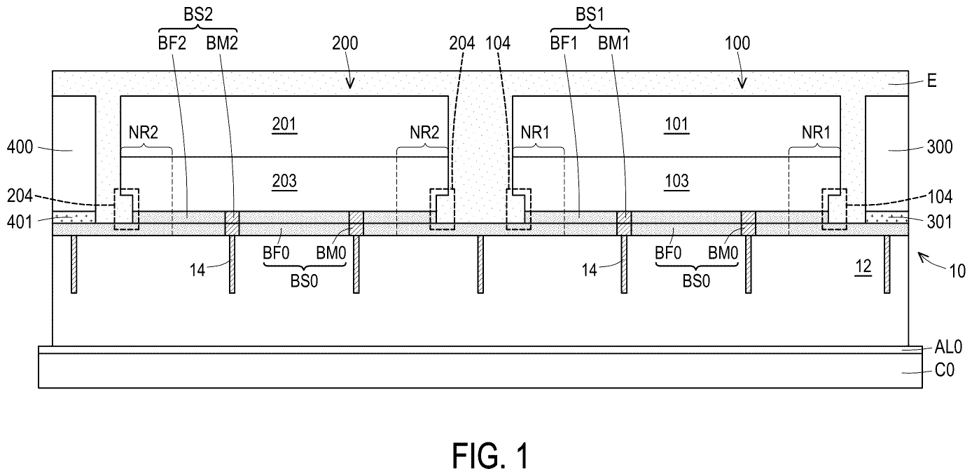

FIG. 1 to FIG. 8 are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 8 are described in relation to a method, it is appreciated that the structures disclosed in FIG. 1 to FIG. 8 are not limited to such a method, but instead may stand alone as structures independent of the method.

Referring to FIG. 1, an interposer structure 10 is provided on a carrier C0. In some embodiments, the carrier C0 includes a glass carrier or a ceramic carrier. The carrier C0 may have an adhesive layer AL0 thereon, and the interposer structure 10 is attached to the adhesive layer AL0. The adhesive layer AL0 includes a light-to-heat-conversion (LTHC) film, or the like.

In some embodiments, the interposer structure 10 includes a substrate 12, and through vias 14 extending from one side to the opposite side of the substrate 12. In some embodiments, the interposer structure 10 is a silicon-containing interposer. The substrate 12 may include elementary semiconductor such as silicon, germanium and/or a compound semiconductor such as silicon germanium, silicon carbide, gallium arsenic, indium arsenide, gallium nitride or indium phosphide, and the through vias 14 may include metal such as copper and insulated from the semiconductor substrate 12 by insulating liners. In other embodiments, the interposer structure 10 is an organic interposer or a glass interposer. The substrate 12 may include a dielectric material, and the through vias 14 may include metal such as copper. The through vias 14 may not penetrate through the substrate 12 at this stage.

In some embodiments, the interposer structure 10 further includes an interposer bonding structure BS0 electrically connected to the through vias 14. In some embodiments, the interposer bonding structure BS0 includes bonding metal features BM0 embedded in a dielectric bonding film BF0. In some embodiments, the dielectric bonding film BF0 includes silicon, silicon oxide, silicon nitride, silicon oxynitride, a polymer or a combination thereof. In some embodiments, the bonding metal features BM0 include bonding pads, bonding vias or a combination thereof. The bonding metal features BM0 are active bonding metal features for providing electrical connection to an electrical component. In some embodiments, the interposer bonding structure BS0 may include dummy bonding metal features (not shown) at a floating potential for improving the bonding performance. The bonding metal features BM0 may include Cu, Ti, Ta, W, Ru, Co, Ni, the like, or a combination thereof. In some embodiments, a seed layer and/or a barrier layer may be disposed between each bonding metal feature and the dielectric bonding film. The seed layer may include Ti/Cu. The barrier layer may include Ta, TaN, Ti, TiN, CoW or a combination thereof.

In some embodiments, the interposer structure 10 is an active interposer that contains at least one functional device or integrated circuit device included on/in the substrate. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 10 is a passive interposer, which is lack of a functional device or integrated circuit device. Such passive interposer is referred to as a “device-free interposer” in some examples.

Continue referring to FIG. 1, multiple semiconductor dies 100 and 200 are provided over and bonded to the interposer structure 10. The semiconductor dies 100 and 200 may have the same or different functions and/or dimensions. Each of the semiconductor dies 100 and 200 may be a logic die, a memory die, a CPU, a GPU, an xPU, a MEMS die, a SoC die, a photonic die or the like. The dimension may be a height, a width, a size, a top-view area or a combination thereof. The semiconductor dies 100 and 200 are referred to as “active dies” or “device-containing dies” in some examples.

In some embodiments, the semiconductor die 100 includes a substrate 101 and a device layer 103. The substrate 101 may include elementary semiconductor such as silicon, germanium and/or a compound semiconductor such as silicon germanium, silicon carbide, gallium arsenic, indium arsenide, gallium nitride or indium phosphide. The substrate 101 may be doped as needed. The device layer 103 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 103 may further include an interconnect structure electrically connected to the transistor, and a passivation layer covering the interconnect structure.

In some embodiments, the semiconductor die 100 further includes a die bonding structure BS1 electrically connected to the interconnect structure of the device layer 103. In some embodiments, the die bonding structure BS1 includes bonding metal features BM1 embedded in a dielectric bonding film BF1. In some embodiments, the dielectric bonding film BF1 includes silicon, silicon oxide, silicon nitride, silicon oxynitride, a polymer or a combination thereof. In some embodiments, the bonding metal features BM1 include bonding pads, bonding vias or a combination thereof. The bonding metal features BM1 are active bonding metal features for providing electrical connection to an electrical component. In some embodiments, the die bonding structure BS1 may include dummy bonding metal features (not shown) at a floating potential for improving the bonding performance. The bonding metal features BM1 may include Cu, Ti, Ta, W, Ru, Co, Ni, the like, or a combination thereof. In some embodiments, a seed layer and/or a barrier layer may be disposed between each bonding metal feature and the dielectric bonding film. The seed layer may include Ti/Cu. The barrier layer may include Ta, TaN, Ti, TiN, CoW or a combination thereof.

In some embodiments, the semiconductor die 100 has a chamfer portion 104 due to the previous die cutting process such as a laser grooving process and/or a shallow plasma dicing (SPD) process, in which the dielectric bonding film BF1 of the die bonding structure BS1, the passivation layer and/or dielectric layers of the interconnect structure of the device layer 103 are removed. The chamfer portion 104 may have a vertical sidewall or an inclined surface. The chamfer portion 104 may be referred to as an “undercut portion” in some examples.

In some embodiments, the semiconductor die 200 includes a substrate 201 and a device layer 203. The substrate 201 may include elementary semiconductor such as silicon, germanium and/or a compound semiconductor such as silicon germanium, silicon carbide, gallium arsenic, indium arsenide, gallium nitride or indium phosphide. The substrate 201 may be doped as needed. The device layer 203 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 203 may further include an interconnect structure electrically connected to the transistor, and a passivation layer covering the interconnect structure.

In some embodiments, the semiconductor die 200 further includes a die bonding structure BS2 electrically connected to the interconnect structure of the device layer 203. In some embodiments, the die bonding structure BS2 includes bonding metal features BM2 embedded in a dielectric bonding film BF2. In some embodiments, the dielectric bonding film BF2 includes silicon, silicon oxide, silicon nitride, silicon oxynitride, a polymer or a combination thereof. In some embodiments, the bonding metal features BM2 include bonding pads, bonding vias or a combination thereof. The bonding metal features BM2 are active bonding metal features for providing electrical connection to an electrical component. In some embodiments, the die bonding structure BS2 may include dummy bonding metal features (not shown) at a floating potential for improving the bonding performance. The bonding metal features BM2 may include Cu, Ti, Ta, W, Ru, Co, Ni, the like, or a combination thereof. In some embodiments, a seed layer and/or a barrier layer may be disposed between each bonding metal feature and the dielectric bonding film. The seed layer may include Ti/Cu. The barrier layer may include Ta, TaN, Ti, TiN, CoW or a combination thereof.

In some embodiments, the semiconductor die 200 has a chamfer portion 204 due to the previous die cutting process such as a laser grooving process and/or a shallow plasma dicing (SPD) process, in which the dielectric bonding film BF2 of the die bonding structure BS2, the passivation layer and/or dielectric layers of the interconnect structure of the device layer 203 are removed. The chamfer portion 204 may have a vertical sidewall or an inclined surface. The chamfer portion 204 may be referred to as an “undercut portion” in some examples.

Still referring to FIG. 1, the semiconductor dies 100 and 200 are bonded to the interposer structure 10 through a mixed bonding including a metal-to-metal bonding and a dielectric-to-dielectric bonding. Specifically, the semiconductor die 100 is bonded to the interposer structure 10 through the die bonding structure BS1 and the interposer bonding structure BS0, in which the bonding metal features BM1 are connected to the bonding metal features BM0, and the dielectric bonding film BF1 is connected to the dielectric bonding film BF0. Similarly, the semiconductor die 200 is bonded to the interposer structure 10 through the die bonding structure BS2 and the interposer bonding structure BS0, in which the bonding metal features BM2 are connected to the bonding metal features BM0, and the dielectric bonding film BF2 is connected to the dielectric bonding film BF0.

In some embodiments, the non-bond region NR1 is defined as an edge bonding area where the delamination occurs at the bonding interface between the dielectric bonding film BF1 and the dielectric bonding film BF0. Similarly, the non-bond region NR2 is defined as an edge bonding area where the delamination occurs at the bonding interface between the dielectric bonding film BF2 and the dielectric bonding film BF0. The film delamination in the non-bond regions NR1 and NR2 may cause package crack issue. The non-bond region may be referred to as a “bonding defect region” in some examples.

In some embodiments, dummy dies 300 and 400 are provided over and bonded to the interposer structure 10 at outer sides of the semiconductor dies 100 and 200. The dummy dies 300 and 400 may be silicon dummy dies for eliminating the coefficient thermal expansion (CTE) mismatch and therefore reducing the package warpage issue. The dummy dies 300 and 400 are referred to as “non-active dies” or “device-free dies” in some examples. In some embodiments, the dummy dies 300 and 400 are attached to the interposer structure 10 through the adhesion layers 301 and 401, respectively. The adhesion layers 301 and 401 may include die attach films (DAF) or the like. In some embodiments, the adhesion layers 301 and 401 may include oxide, and the dummy dies 300 and 400 are bonded to the interposer structure 10 through fusion bonding. The dummy dies 300 and 400 are optional and may be omitted as needed.

Thereafter, an encapsulation layer E is formed over the interposer structure 10 around the dies 100, 200, 300 and 400. In some embodiments, the encapsulation layer E covers the tops of the dies 100, 200, 300 and 400 and fills in gaps between the dies 100, 200, 300 and 400. The encapsulation layer E further fills in the chamfer portions 104 and 204 of the semiconductor dies 100 and 200. In some embodiments, the encapsulation layer E includes a molding compound, a molding underfill, a resin or the like. In some embodiments, the encapsulation layer E includes a polymer material such as polybenzoxazole (PBO), polyimide, benzocyclobutene (BCB), the like, or a combination thereof. In some embodiments, the method of forming the encapsulation layer E includes performing a molding process followed by a curing process.

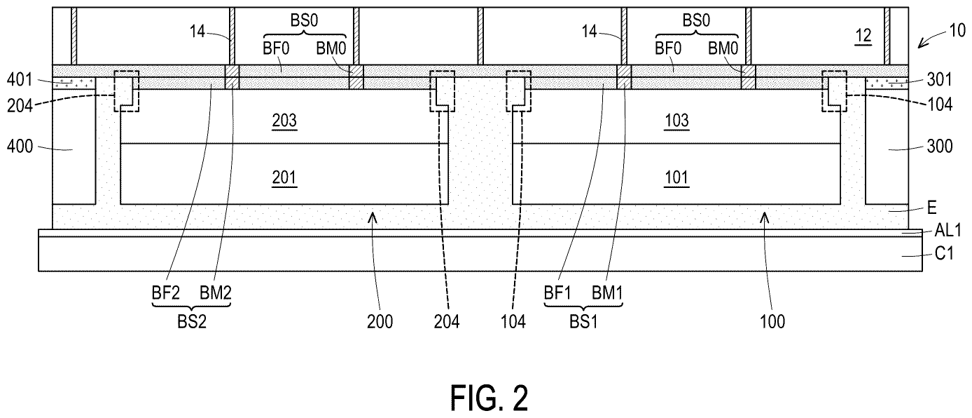

Referring to FIG. 2, the structure of FIG. 1 is turned over and bonded to a carrier C1 with the encapsulation layer E facing the carrier C1. In some embodiments, the carrier C1 includes a glass carrier or a ceramic carrier. The carrier C0 may have an adhesive layer AL1 thereon, and the encapsulation layer E is attached to the adhesive layer AL1. The adhesive layer AL1 includes a light-to-heat-conversion (LTHC) film, or the like.

Thereafter, the carrier C0 and the adhesive layer AL0 are removed. In some embodiments, the adhesive layer AL0 is decomposed under heat of light, and the carrier C0 is then released from the structure formed thereon.

Afterwards, the substrate 12 of the interposer structure 10 is thinned, until the surfaces of the through vias 104 are exposed. The thinning process includes a polishing process, a grinding process or a combination thereof.

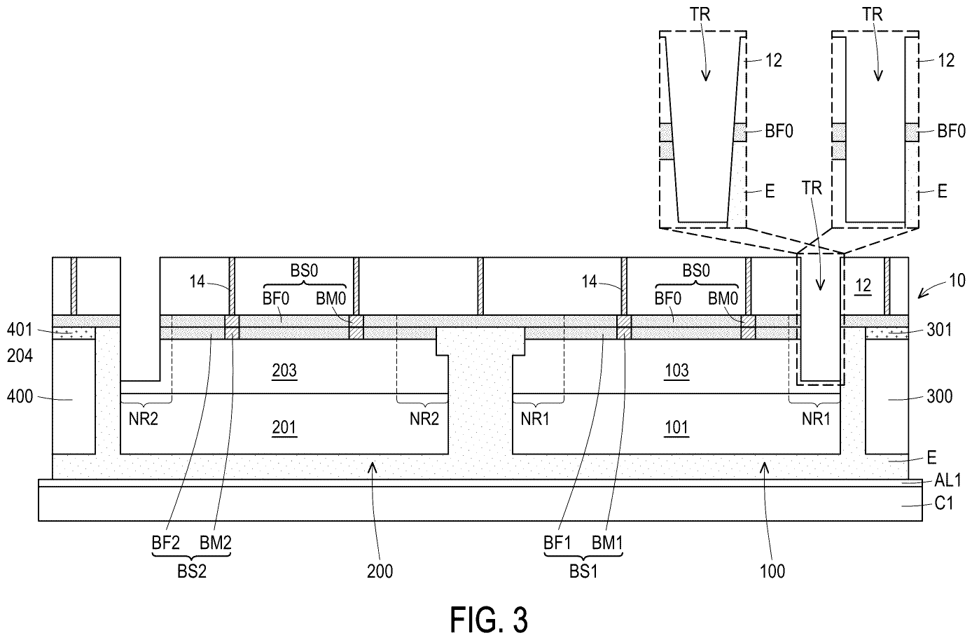

Referring to FIG. 3, a trench TR is formed along a periphery of the semiconductor dies 100 and 200, so as to remove at least portions of the non-bond regions NR1 and NR2 and therefore avoid the package crack issue. In some embodiments, from a top view, the trench TR may have a ring shape, an island shape, a bar shape, an L-shape, a T-shape, the like or a combination thereof. In some embodiments, from a top view, the trench TR is a single continuous trench ring across the semiconductor dies 100 and 200, but the disclosure is not limited to. In other embodiments, from a top view, the trench TR may include discrete opening patterns arranged along the peripheries of the semiconductor dies 100 and 200, respectively. In some embodiments, the trench TR penetrates through the interposer structure 10 and extending into portions of the semiconductor dies 100 and 200. Specifically, the trench TR penetrates through the substrate 12 of the interposer structure 10, the dielectric bonding film of the interposer bonding structure BS0, and the die bonding film BS1/BS2 of the semiconductor die 100/200, and further extends into the passivation layer and/or dielectric layers of the interconnect structure of the device layer 103/203. The trench TR is formed through the non-metal portions (e.g., dielectric portions and/or semiconductor portions) of the interposer structure 10 and the semiconductor dies 100 and 200. The trench TR is separated from metal materials of the interposer structure 10 and the semiconductor dies 100 and 200. In some embodiments, the method of forming the trench TR includes performing a laser grooving process, but the present disclosure is not limited thereto. In other embodiments, the trench TR is formed by photolithography etching processes. The trench TR may be formed to have a substantially vertical sidewall or an inclined sidewall, as shown in the local views in FIG. 3. In some embodiments, the width of the trench TR ranges from about 15 um to 25 um, but other ranges may be applicable.

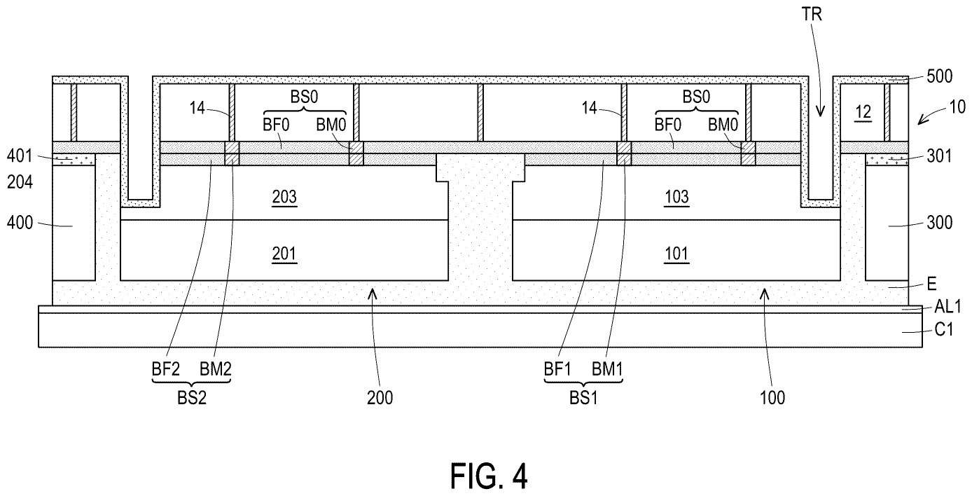

Referring to FIG. 4, a liner layer 500 is formed on the surface of the interposer structure 10 and on the sidewall and the bottom of the trench TR. Specifically, the liner layer 500 is in contact with the non-metal portions (e.g., dielectric portions and/or semiconductor portions) of the interposer structure 10 and the semiconductor dies 100 and 200. In some embodiments, the liner layer 500 includes silicon oxide, silicon nitride, silicon oxynitride, Al₂O₃, or the like. In some embodiments, the method of forming the liner layer 500 includes performing a chemical vapor deposition (CVD) process. The liner layer is referred to an “insulating liner” or “dielectric liner” in some examples. The liner layer 500 is optional and may be omitted as needed.

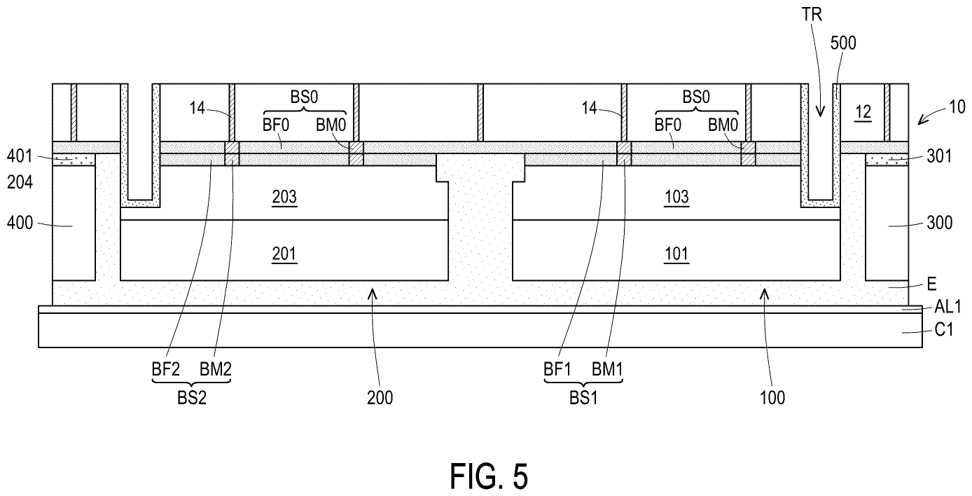

Referring to FIG. 5, the liner layer 500 is removed from the surface of the interposer structure 10. In some embodiments, the method of removing the liner layer 500 includes performing a chemical mechanical polishing (CMP) process.

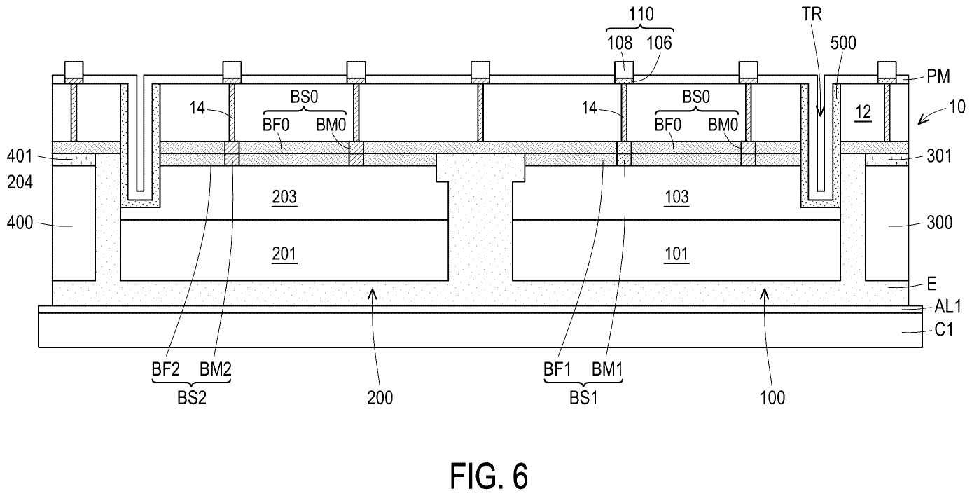

Referring to FIG. 6, a polymer layer PM is formed on the surface of the interposer structure 10 and on the sidewall and the bottom of the trench TR. In some embodiments, the polymer layer PM is formed over and in contact with the liner layer 500, but the disclosure is not limited thereto. In some embodiments, the polymer layer PM is in contact with non-metal portions (e.g., dielectric portions and/or semiconductor portions) of the interposer structure 10 and the semiconductor dies 100 and 200 when the liner layer 500 is optionally omitted. In some embodiments, the polymer layer PM includes polybenzoxazole (PBO), polyimide, benzocyclobutene (BCB), the like, or a combination thereof. In some embodiments, the method of forming the polymer layer PM includes performing a spin coating process.

Thereafter, interposer connectors 110 are formed on the side of the interposer structure 10 opposite to the semiconductor dies 100 and 200. Specifically, the interposer connectors 110 penetrate through the polymer layer PM and are electrically connected to the through vias 14 of the interposer structure 10. In some embodiments, each interposer connector 110 includes a metal pad 106 and a bump 108. The metal pad may include Cu, Ti, Ta, W, Ru, Co, Ni, the like, or a combination thereof. The bump 108 may include solder or the like. In some embodiments, the method of forming the interposer connectors 110 includes performing an electroplating process. The interposer connectors 110 are referred to as “controlled collapse chip connection (C4) bumps” in some examples.

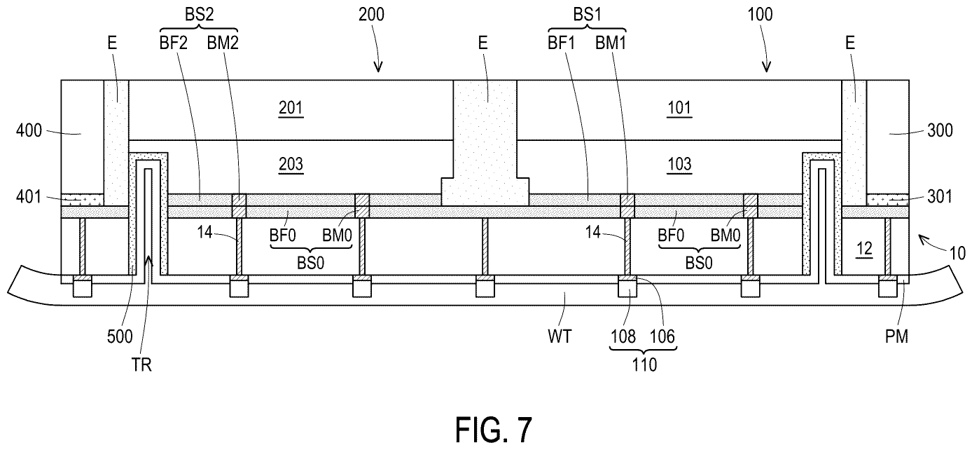

Referring to FIG. 7, the structure of FIG. 6 is turned over and attached to a wafer tape WT with the interposer connectors 110 facing the wafer tape WT. Thereafter, the carrier C1 and the adhesive layer AL1 are removed. In some embodiments, the adhesive layer AL1 is decomposed under heat of light, and the carrier C1 is then released from the structure formed thereon.

Afterwards, the encapsulation layer E is removed until the substrates 101 and 201 of the semiconductor dies 100 and 200 are exposed. The removing process includes a polishing process, a grinding process or a combination thereof.

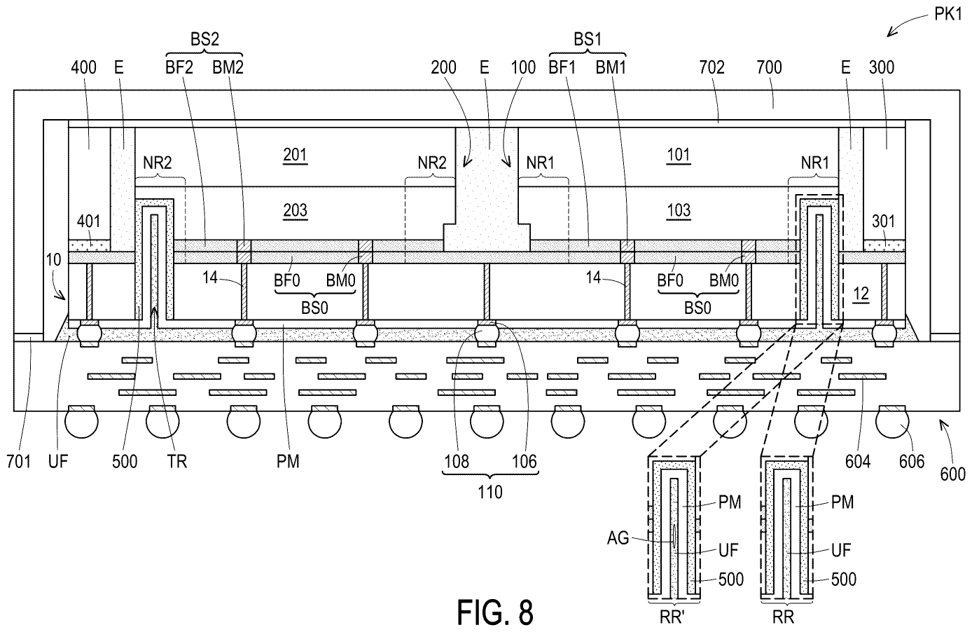

Referring to FIG. 8, the wafer tape WT is removed, and a board substrate 600 is formed below and electrically connected to the interposer structure 10. In some embodiments, the board substrate 600 is bonded to the interposer structure 10 through the interposer connectors 110.

In some embodiments, the board substrate 600 includes a core layer and two build-up layers on opposite sides of the core layer. In some embodiments, the board substrate 600 includes wiring patterns 604 that penetrate through the core layer and the build-up layers for providing electrical routing between different devices and electric components. The wiring patterns 604 include metal lines, metal vias, metal pads and/or metal connectors. The board substrate 600 is referred to as a “printed circuit board (PCB)” in some examples. In other embodiments, the core layer of the board substrate 600 may be omitted as needed, and such board substrate 600 is referred to as a “coreless board substrate”.

Thereafter, an underfill layer UF is formed to fill the space between the interposer structure 10 and the board substrate 600, and surrounds the interposer connectors 110. In some embodiments, the underfill layer UF includes a molding compound such as epoxy, and is formed using dispensing, injecting, and/or spraying process. The underfill layer UF further flows into the trench TR. In some embodiments, the underfill layer UF completely fills the trench TR. In other embodiments, the underfill UF does not completely fill the trench TR, and an air gap AG is present in the trench TR. Two possible scenarios are shown in the local views of FIG. 8. In the disclosure, the liner layer 500, the polymer layer PM and the underfill layer UF in the trench TR constitute a repairing ring RR/RR′ for repairing the delamination issue in the non-bond regions NR1 and NR2 of the semiconductor dies 100 and 200. The repairing ring RR/RR′ is referred to as an “defect repairing ring”, “insulating pattern” or “stress releasing ring” in some examples.

Thereafter, a heat dissipation structure 700 is attached to the board substrate 700 by an adhesive layer 701. The heat dissipation structure 700 may include a ring, a lid, heat sink fins, a combination thereof, or other suitable structures. The heat dissipation structure 700 is configured to reduce warpage and improve the heat dissipation performance. The heat dissipation structure 700 has a high thermal conductivity greater than about 100 W/m*K, for example, and may be formed using a metal, a metal alloy, or the like. For example, the heat dissipation structure 700 may include a metal or a metal alloy, with the respective metals selected from the group consisting of Al, Cu, Ni, Co, and the like. The heat dissipation structure 700 may also be formed of a composite material selected from the group consisting of silicon carbide, aluminum nitride, graphite, and the like. In some embodiments, the adhesive layer 701 includes a tape or a suitable glue material.

In some embodiments, a thermal interface material (TIM) 702 is disposed between the heat dissipation structure 700 and each of the dies 100, 200, 300 and 400 and the encapsulation layer E. The thermal interface material 702 has a good thermal conductivity, which may be greater than about 2 W/m*K, and may be as equal to, or higher than, about 10 W/m*K or 50 W/m*K. In some embodiments, the thermal interface material 702 is made of silicones, which are polymers including silicon, carbon, hydrogen, oxygen and sometimes other elements. In other embodiments, the thermal interface material 702 may also be made of other materials, such as alumina (Al₂O₃) or zinc oxide (ZnO₂) mixed with silicone and other applicable materials.

Thereafter, connectors 606 are formed below and electrically connected to the board substrate 600. In some embodiments, the connectors 606 are electrically to the wiring patterns 604 of the board substrate 600. In some embodiments, the connectors 606 may include solder bumps, and/or may include metal pillars (e.g., copper pillars), solder caps formed on metal pillars, and/or the like. The connectors 606 are referred to as “ball grid array (BGA) balls” in some examples. The size of the connectors 606 may be different from (e.g., greater than) the size of the interposer connectors 110. A semiconductor package PK1 of the disclosure is thus completed.

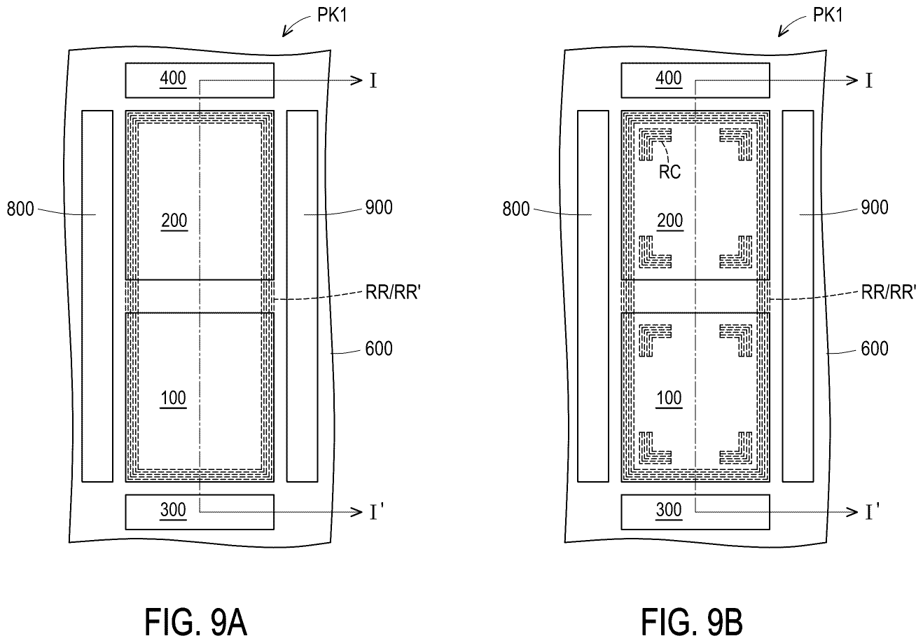

FIG. 9A and FIG. 9B are simplified local top views of semiconductor packages in accordance with some embodiments. For clarity and illustration purposes, only few components such as dies, an interposer structure, a repairing ring and a board substrate are shown in FIG. 9A and FIG. 9B. In some embodiments, FIG. 1 to FIG. 8 are schematic cross-sectional views of a semiconductor package taken along the line I-I of FIG. 9A and FIG. 9B.

In the top view of FIG. 9A, dies 100, 200, 300, 400, 800 and 900 are disposed over the underlying board substrate 600. In some embodiments, the dies 100 and 200 are active dies hybrid-bonded to the underlying interposer structure 10 and therefore overlying the board substrate 600, as shown in FIG. 8. A repairing ring RR/RR′ is disposed along the periphery of the semiconductor dies 100 and 200, configured to repair the delamination issue in the non-bond regions NR1 and NR2 of the semiconductor dies 100 and 200. In some embodiments, the dies 300, 400, 800 and 900 are dummy dies disposed at four sides of the repairing ring RR/RR'. The dummy dies 300, 400, 800 and 900 are adhered to the underlying interposer structure 10 through adhesion layers and therefore overlying the board substrate 600, as shown in FIG. 8. The dummy dies 300, 400, 800 and 900 may be silicon dummy dies for eliminating the coefficient thermal expansion (CTE) mismatch and therefore reducing the package warpage issue. The dummy dies 300, 400, 800 and 900 are referred to as “non-active dies” or “device-free dies” in some examples. The dummy dies 300, 400, 800 and 900 are optional and may be omitted as needed.

In some embodiments, in addition to the dies 100, 200, 300, 400, 800 and 900, other devices may also be mounted on the board substrate 600. For example, the semiconductor dies 100 and 200 may be logic dies, and additional memory dies may be attached to the board substrate 600 through soldering or other methods, with additional underfill layers formed between the memory dies and the board substrate 600. In some embodiments, passive devices (e.g., capacitors, resistors, inductors, varactors, and/or similar components) are also mounted on the board substrate 600, for instance, using surface mount technology (SMT) connections.

In addition to the repairing ring RR/RR', multiple repairing patterns RC are further provided around corners of each of the semiconductor dies 100 and 200, as shown in the top view of FIG. 9B. The repairing patterns RC are beneficial to eliminate the film deamination issue at chip corners. The repairing patterns RC may have a L-shape, an island shape or a suitable shape. The repairing patterns RC and the repairing ring RR/RR′ are formed by the same process steps and therefore have the same composition. Specifically, each of the repairing patterns RC and the repairing ring RR/RR′ includes, from outer to inner, an optional liner layer 500, a polymer layer PM, an underfill layer UF and an optional air gap AG, as shown in the cross-sectional view of FIG. 8. The repairing patterns RC are referred to as “defect repairing patterns”, “insulating segments” or “stress releasing patterns” in some examples.

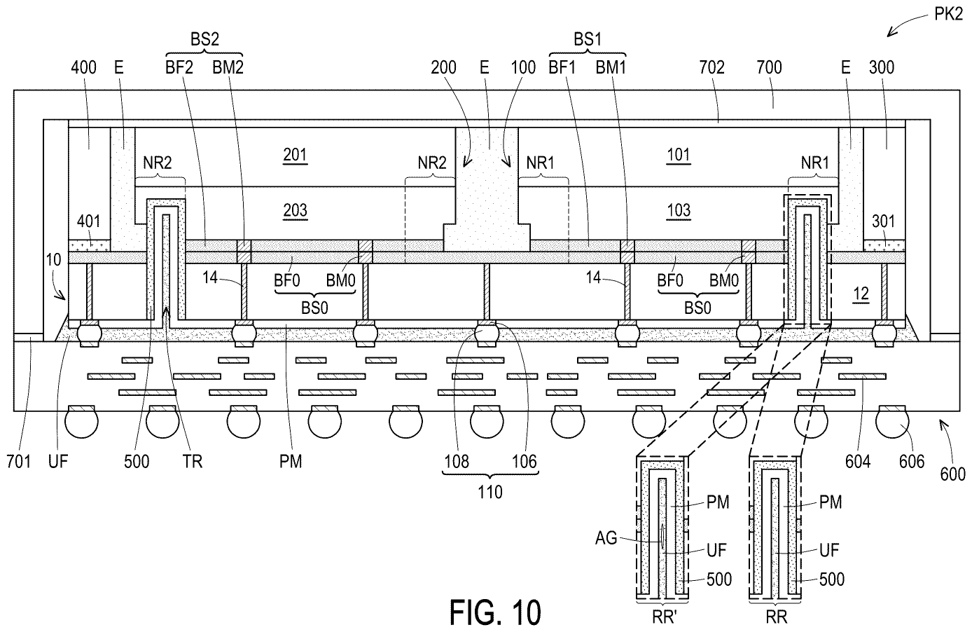

In the above embodiments, the outer sidewall of the repairing ring RR/RR′ is substantially flush with the outer sidewall of the semiconductor die 100/200, but the disclosure is not limited thereto. In other embodiments, the outer sidewall of the repairing ring RR/RR′ is offset from the outer sidewall of the semiconductor die 100/200, as shown in FIG. 10 to FIG. 13B.

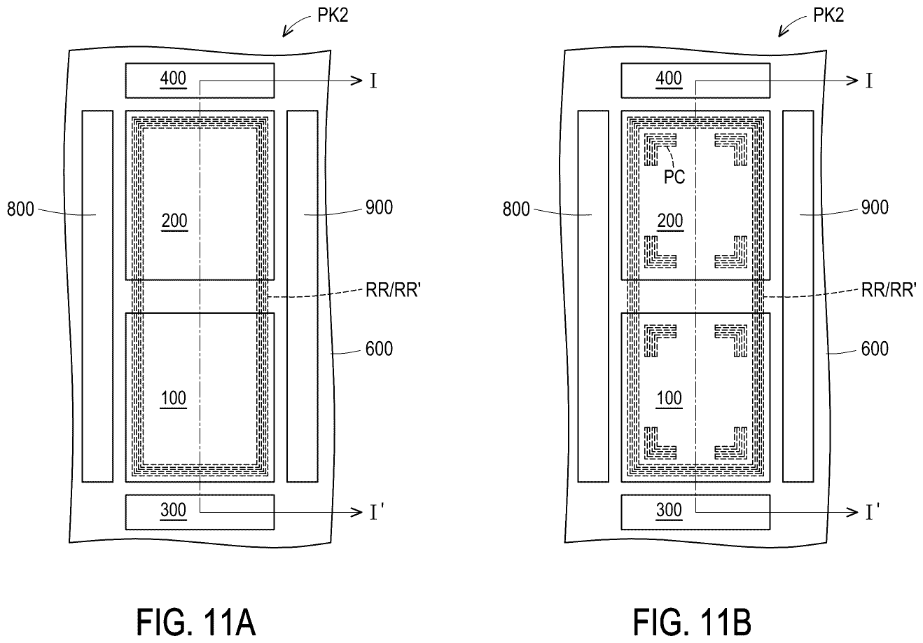

FIG. 10 is a schematic cross-sectional view of a semiconductor package in accordance with some embodiments. FIG. 11A and FIG. 11B are simplified local top views of semiconductor packages in accordance with some embodiments. For clarity and illustration purposes, only few components such as dies, an interposer structure, a repairing ring and a board substrate are shown in FIG. 11A and FIG. 11B. In some embodiments, FIG. 10 is a schematic cross-sectional view of a semiconductor package taken along the line I-I of FIG. 11A and FIG. 11B.

The semiconductor package PK2 of FIG. 10 is similar to the semiconductor package PK1 of FIG. 8, so the difference is illustrated in details below, and the similarity is not iterated herein. The difference between the semiconductor package PK2 of FIG. 10 and the semiconductor package PK1 of FIG. 8 lies in that, the outer sidewall of the repairing ring RR/RR′ is recessed from the outer sidewall of the semiconductor die 100/200 by a non-zero distance. As shown in the top view of FIG. 11A and FIG. 11B, the repairing ring RR/RR′ is misaligned with the sidewalls of the semiconductor dies 100 and 200 facing the dummy dies 300, 400, 800 and 900.

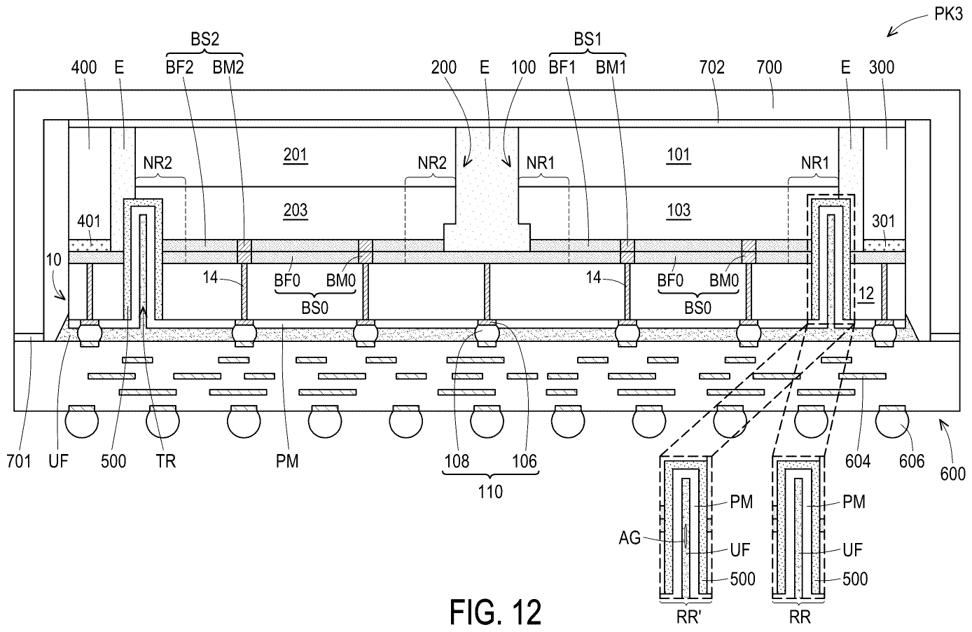

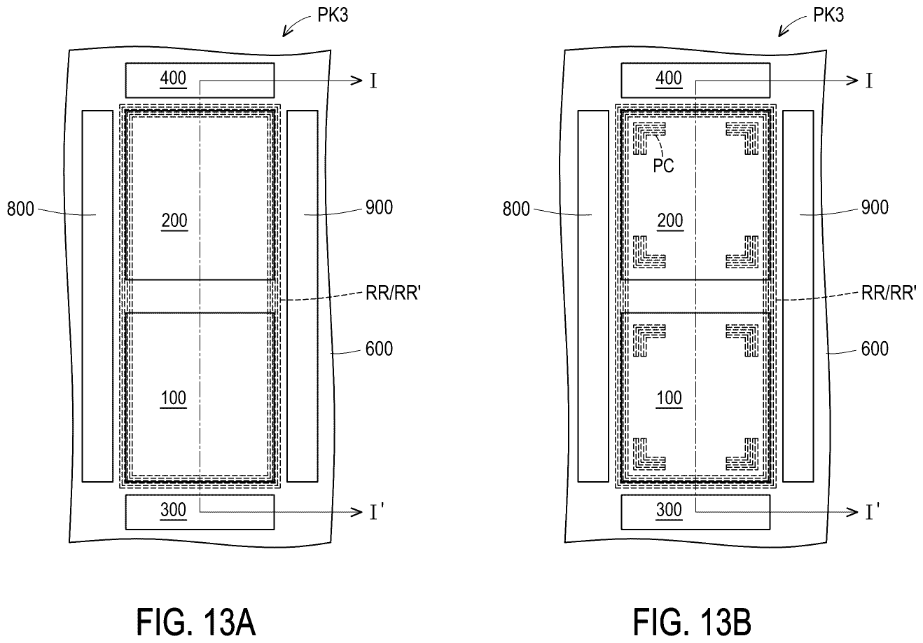

FIG. 12 is a schematic cross-sectional view of a semiconductor package in accordance with some embodiments. FIG. 13A and FIG. 13B are simplified local top views of semiconductor packages in accordance with some embodiments. For clarity and illustration purposes, only few components such as dies, an interposer structure, a repairing ring and a board substrate are shown in FIG. 13A and FIG. 13B. In some embodiments, FIG. 12 is a schematic cross-sectional view of a semiconductor package taken along the line I-I of FIG. 13A and FIG. 13B.

The semiconductor package PK3 of FIG. 12 is similar to the semiconductor package PK1 of FIG. 8, so the difference is illustrated in details below, and the similarity is not iterated herein. The difference between the semiconductor package PK3 of FIG. 12 and the semiconductor package PK1 of FIG. 8 lies in that, the outer sidewall of the repairing ring RR/RR′ is protruded from the outer sidewall of the semiconductor die 100/200 by a non-zero distance. As shown in the top view of FIG. 12A and FIG. 12B, the repairing ring RR/RR′ is overlapped with the sidewalls of the semiconductor dies 100 and 200 facing the dummy dies 300, 400, 800 and 900.

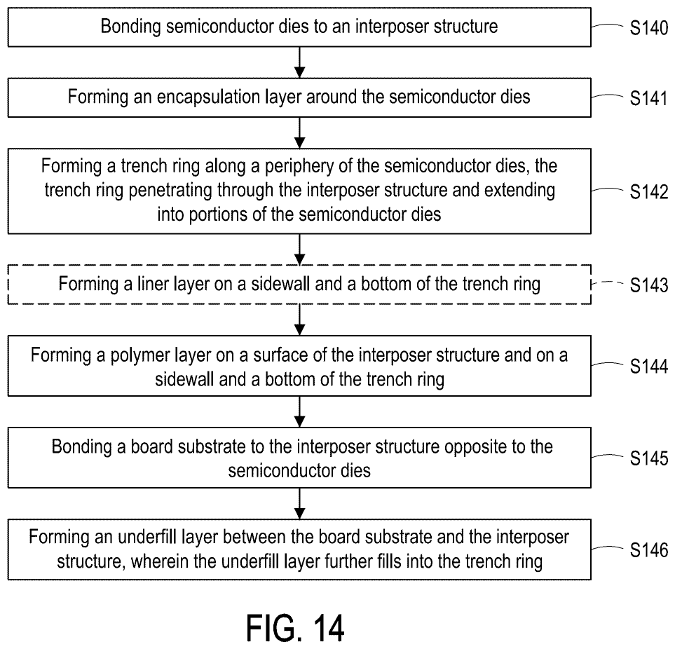

FIG. 14 illustrates a method of forming a package structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S140, semiconductor dies are bonded to an interposer structure. FIG. 1 illustrates a cross-sectional view corresponding to some embodiments of act S140. In some embodiments, the interposer structure has an interposer bonding structure, each of the semiconductor die has an die bonding structure, and the semiconductor dies are bonded to the interposer structure through the interposer bonding structure and the die boding structures.

At act S141, an encapsulation layer is formed around the semiconductor dies. FIG. 1 illustrates a cross-sectional view corresponding to some embodiments of act S141.

At act S142, a trench is formed along a periphery of the semiconductor dies, and the trench penetrates through the interposer structure and extending into portions of the semiconductor dies. FIG. 2 to FIG. 3 illustrate cross-sectional views corresponding to some embodiments of act S142. In some embodiments, the method of forming the trench includes performing a laser grooving process. In some embodiments, the trench penetrates through the interposer bonding structure and the die boding structures. In some embodiments, multiple trench patterns are formed around corners of the semiconductor dies during the operation of forming the trench. Specifically, the trench patterns and the trench are formed by the same laser grooving process.

At act S143, a liner layer is formed on a sidewall and a bottom of the trench. FIG. 4 to FIG. 5 illustrate cross-sectional views corresponding to some embodiments of act S143. Act S143 is optional and may be omitted as needed.

At act S144, a polymer layer is formed on a surface of the interposer structure and on a sidewall and a bottom of the trench. FIG. 6 illustrates a cross-sectional view corresponding to some embodiments of act S144.

At act S145, a board substrate is bonded to the interposer structure opposite to the semiconductor dies. FIG. 7 to FIG. 8 illustrate cross-sectional views corresponding to some embodiments of act S145.

At S146, an underfill layer is formed between the board substrate and the interposer structure, and the underfill layer fills into the trench. FIG. 8 illustrates a cross-sectional view corresponding to some embodiments of act S146. In some embodiments, the underfill layer completely fills the trench. In other embodiments, at least one air gap is present in the trench after forming the underfill layer.

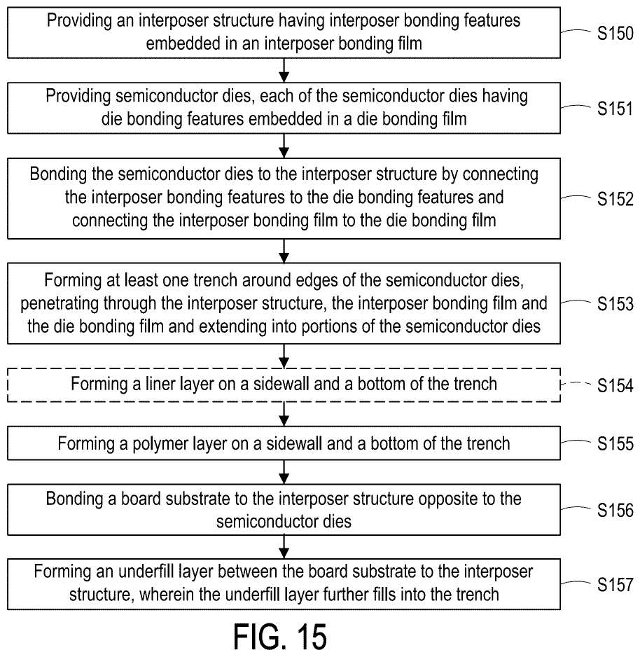

FIG. 15 illustrates a method of forming a package structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S150, an interposer structure is provided, and the interposer structure has interposer bonding features embedded in an interposer bonding film. FIG. 1 illustrates a cross-sectional view corresponding to some embodiments of act S150.

At act S151, semiconductor dies are provided, and each of the semiconductor dies has die bonding features embedded in a die bonding film. FIG. 1 illustrates a cross-sectional view corresponding to some embodiments of act S151.

At act S152, the semiconductor dies are bonded to the interposer structure by connecting the interposer bonding features to the die bonding features and connecting the interposer bonding film to the die bonding film. FIG. 1 illustrates a cross-sectional view corresponding to some embodiments of act S152.

At act S153, at least one trench is formed around edges of the semiconductor dies, and the at least one trench penetrates through the interposer structure, the interposer bonding film and the die bonding film and extends into portions of the semiconductor dies. FIG. 2 to FIG. 3 illustrate cross-sectional views corresponding to some embodiments of act S153. In some embodiments, the method of forming the at least one trench includes performing a laser grooving process. In some embodiments, the at least one trench includes a continuous trench along a periphery of the semiconductor dies, separate trench patterns around corners of the semiconductor dies, or a combination thereof.

At act S154, a liner layer is formed on a sidewall and a bottom of the trench. FIG. 4 to FIG. 5 illustrate cross-sectional views corresponding to some embodiments of act S154. Act S154 is optional and may be omitted as needed.

At act S155, a polymer layer is formed on a sidewall and a bottom of the trench. FIG. 6 illustrates a cross-sectional view corresponding to some embodiments of act S155.

At act S156, a board substrate is bonded to the interposer structure opposite to the semiconductor dies. FIG. 7 to FIG. 8 illustrate cross-sectional views corresponding to some embodiments of act S156.

At act S157, an underfill layer is formed between the board substrate to the interposer structure, and the underfill layer further fills into the trench. FIG. 8 illustrates a cross-sectional view corresponding to some embodiments of act S157. In some embodiments, the underfill layer completely fills the trench. In other embodiments, at least one air gap is present in the trench after forming the underfill layer.

The structures of the semiconductor packages of the disclosure are described below with reference to FIG. 8 to FIG. 13B.

In some embodiments, a semiconductor package PK1/PK2/PK3 includes an interposer structure 10, semiconductor dies 100 and 200, an encapsulation layer E and an insulating pattern RR/RR'. The semiconductor dies 100 and 200 are disposed on the interposer structure 10. The encapsulation layer E is disposed around the semiconductor dies 100 and 200. The insulating pattern RR/RR′ is disposed along a periphery of the semiconductor dies 100 and 200, penetrates through the interposer structure 10 and extends into portions of the semiconductor dies 100 and 200.

In some embodiments, the insulating pattern RR/RR′ is void-free. In some embodiments, at least one air gap AG is present in the insulating pattern.

In some embodiments, a board substrate 600 is further provided and disposed below the interposer structure 10, and the board substrate 600 faces the insulating pattern RR/RR′.

In some embodiments, an underfill layer UF is further provided and disposed between the interposer structure 10 and the board substrate 600, and a portion of the underfill layer UF extends into insulating pattern RR/RR′ and constitutes a part of the insulating pattern RR/RR′.

In some embodiments, insulating segments RC are further included and disposed around corners of each of the semiconductor dies 100 and 200. In some embodiments, the insulating segments RC and the insulating pattern RR/RR′ contain the same composition, such as including, from outer to inner, an optional liner layer 500, a polymer layer PM, an underfill layer UF and an optional air gap AG. However, the disclosure is not limited thereto. In other embodiments, the insulating segments RC and the insulating pattern RR/RR′ may include different compositions. For example, the widths of the insulating segments RC may be different from the width of the insulating pattern RR/RR′. When the widths of the insulating segments RC are less than the width of the insulating pattern RR/RR′, the liner layer 500 and the polymer layer PM may completely fill the trench patterns for the insulating segments RC, and thus, the insulating segments RC are free of an underfill material.

In some embodiments, from a top view, the outer sidewall of the insulating pattern RR/RR′ is coincided with the outer sidewalls of the semiconductor dies 100 and 200 facing a periphery of the board substrate 600. In some embodiments, from a top view, the outer sidewall of the insulating pattern RR/RR′ is offset from the outer sidewalls of the semiconductor dies 100 and 200 facing a periphery of the board substrate 600.

In some embodiments, the insulating pattern RR/RR′ is a single continuous ring across the semiconductor dies 100 and 200, but the disclosure is not limited to. In other embodiments, the insulating pattern RR/RR′ may include discrete ring patterns arranged along the peripheries of the semiconductor dies 100 and 200, respectively. The outer sidewall of each of the ring patterns may be coincided with or offset from the outer sidewalls of the semiconductor dies 100 and 200 facing a periphery of the board substrate 600.

In view of above, in the disclosure, a trench is formed to remove the delaminated edge region of the bonding area between the die and the underlying interposer, and the trench is then filled with insulating materials. By such manner, the delaminated edge region is removed, the bonding performance is improved, the bonding stress is mitigated, and the package reliability is accordingly enhanced.

Many variations of the above examples are contemplated by the disclosure. It is understood that different embodiments may have different advantages, and that no particular advantage is necessarily required of all embodiments.

In accordance with some embodiments of the present disclosure, a method of forming a semiconductor package includes the following operations. Semiconductor dies are bonded to an interposer structure. An encapsulation layer is formed around the semiconductor dies. A trench is formed along a periphery of the semiconductor dies, and the trench penetrates through the interposer structure and extends into portions of the semiconductor dies.

In accordance with some embodiments of the present disclosure, a method of forming a semiconductor package includes following operations. An interposer structure is provided, the interposer structure has interposer bonding features embedded in an interposer bonding film. Semiconductor dies are provided, and each of the semiconductor dies has die bonding features embedded in a die bonding film. The semiconductor dies are bonded to the interposer structure by connecting the interposer bonding features to the die bonding features and connecting the interposer bonding film to the die bonding film. At least one trench is formed around edges of the semiconductor dies, the at least one trench penetrating through the interposer structure, the interposer bonding film and the die bonding film and extending into portions of the semiconductor dies.

In accordance with some embodiments of the present disclosure, a semiconductor package includes an interposer structure, semiconductor dies, an encapsulation layer and an insulating pattern. The semiconductor dies are disposed on the interposer structure. The encapsulation layer is disposed around the semiconductor die. The insulating pattern is disposed along a periphery of the semiconductor dies, penetrates through the interposer structure and extends into portions of the semiconductor dies.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor package, comprising:
bonding semiconductor dies to an interposer structure;
forming an encapsulation layer around the semiconductor dies;
forming a trench along a periphery of the semiconductor dies, the trench penetrating through the interposer structure and extending into portions of the semiconductor dies; and
forming a polymer layer on a surface of the interposer structure and on a sidewall and a bottom of the trench.

2. The method of claim 1, wherein the interposer structure has an interposer bonding structure, each of the semiconductor die has an die bonding structure, and the semiconductor dies are bonded to the interposer structure through the interposer bonding structure and the die boding structures.

3. The method of claim 2, wherein the trench penetrates through the interposer bonding structure and the die boding structures.

4. The method of claim 1, wherein a method of forming the trench comprises performing a laser grooving process.

5. The method of claim 1, further comprising, after forming the trench and before forming the polymer layer, forming a liner layer on the sidewall and the bottom of the trench.

6. The method of claim 1, further comprising:
bonding a board substrate to the interposer structure opposite to the semiconductor dies; and
forming an underfill layer between the board substrate and the interposer structure, wherein the underfill layer further fills into the trench.

7. The method of claim 6, wherein the underfill layer completely fills the trench.

8. The method of claim 7, wherein at least one air gap is present in the trench after forming the underfill layer.

9. A method of forming a semiconductor package, comprising:
providing an interposer structure having interposer bonding features embedded in an interposer bonding film;
providing semiconductor dies, each of the semiconductor dies having die bonding features embedded in a die bonding film;
bonding the semiconductor dies to the interposer structure by connecting the interposer bonding features to the die bonding features and connecting the interposer bonding film to the die bonding film; and
forming at least one trench around edges of the semiconductor dies, the at least one trench penetrating through the interposer structure, the interposer bonding film and the die bonding film and extending into portions of the semiconductor dies.

10. The method of claim 9, wherein a method of forming the at least one trench comprises performing a laser grooving process.

11. The method of claim 9, wherein the at least one trench comprises a continuous trench ring along a periphery of the semiconductor dies, separate trench patterns around corners of the semiconductor dies, or a combination thereof.

12. The method of claim 9, further comprising forming a liner layer on a sidewall and a bottom of the trench.

13. The method of claim 9, further comprising forming a polymer layer on a sidewall and a bottom of the trench.

14. The method of claim 9, further comprising:
bonding a board substrate to the interposer structure opposite to the semiconductor dies; and
forming an underfill layer between the board substrate to the interposer structure, wherein the underfill layer further fills into the trench.

15. A semiconductor package, comprising:
an interposer structure;
semiconductor dies disposed on the interposer structure;
an encapsulation layer disposed around the semiconductor dies; and
an insulating pattern disposed along a periphery of the semiconductor dies, penetrating through the interposer structure and extending into portions of the semiconductor dies.

16. The semiconductor package of claim 15, wherein the insulating pattern is void-free.

17. The semiconductor package of claim 15, wherein at least one air gap is present in the insulating pattern.

18. The semiconductor package of claim 15, further comprising a board substrate disposed below the interposer structure and facing the insulating pattern.

19. The semiconductor package of claim 18, further comprising an underfill layer disposed between the interposer structure and the board substrate, wherein a portion of the underfill layer extends into insulating pattern and constitutes a part of the insulating pattern.

20. The semiconductor package of claim 15, further comprising insulating segments around corners of each of the semiconductor dies.
